(19) United States
(12) Patent Application Publication
(10) Pub. No.: US 2023/0223320 A1
(43) Pub. Date: Jul. 13, 2023

(54) SEMICONDUCTOR DEVICE PACKAGE AND METHOD FOR MANUFACTURING THE SAME

(71) Applicant: NEXPERIA B.V., Nijmegen (NL)

(72) Inventors: Ricardo Yandoc, Nijmegen (NL); Adam Brown, Nijmegen (NL); Zhou Zhou, Nijmegen (NL)

(73) Assignee: NEXPERIA B.V., Nijmegen (NL)

(21) Appl. No.: 18/153,688

(22) Filed: Jan. 12, 2023

(30) Foreign Application Priority Data
Jan. 12, 2022 (EP) 22151115.7

(51) Int. Cl. H01L 23/495; H01L 23/00; H01L 23/34; H01L 23/31; H01L 21/48

(52) U.S. Cl. CPC H01L 23/49503; H01L 23/562; H01L 23/34; H01L 23/3121; H01L 21/4842; H01L 23/49568

(57) ABSTRACT

A semiconductor device package and a method for manufacturing the same is provided. The semiconductor device package includes a semiconductor die having an electronic component integrated thereon and having a die terminal that is electrically connected to the electronic component, a stress relief substrate fixedly and electrically connected to the die terminal, and a clip lead. The substrate is configured to provide an electrical short between the clip lead and the die terminal. The stress relief substrate may form an interface between the clip lead and the semiconductor die and can thereby reduce stress exerted on the semiconductor die by the clip lead.

### CROSS-REFERENCE TO RELATED APPLICATIONS

This application claims the benefit under 35 U.S.C. § 119(a) of European Application No. 22151115.7 filed Jan. 12, 2022, the contents of which are incorporated by reference herein in their entirety.

### BACKGROUND

### 1. Field of the Disclosure

Aspects of the present disclosure relate to a semiconductor device package and a method for manufacturing the same. The present disclosure relates particularly to leadframe-based semiconductor device packages.

### 2. Description of the Related Art

Semiconductor device packages typically comprise one or more semiconductor dies on which one or more electronic components are integrated. The semiconductor die(s) is or are generally encapsulated by a package material to protect said semiconductor die(s) from external damage, such as physical or thermal stress. In a leadframe-based package, connections in the form of (clip) leads may be provided that extend from within the package material to an outside of the package to be able to contact one or more terminals of the electronic component(s).

Semiconductor device packages, in particular the semiconductor die(s) thereof, may be susceptible to thermomechanical stress. If the package is placed under stress for an extended period of time, significant and sometimes even permanent damage to the package may ensue, possibly resulting in failure of the semiconductor die(s) or the electronic component(s) integrated thereon.

It is an object of the present disclosure to provide a semiconductor device package for which the abovementioned problem(s) do not occur or hardly so.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

According to an aspect of the present disclosure, a semiconductor device package is provided, comprising a semiconductor die having an electronic component integrated thereon and having a die terminal that is electrically connected to the electronic component, a stress relief substrate fixedly and electrically connected to the die terminal, and a clip lead. The substrate is configured to provide an electrical short between the die terminal and the clip lead.

The Applicant has found that the clip lead is typically a source of thermomechanical stress on the semiconductor die, both during manufacturing (e.g., while providing the clip) and after (e.g., during operational use of the package). The stress relief substrate may form an interface between the clip lead and the semiconductor die and may thereby reduce stress exerted on the semiconductor die by said clip lead.

The substrate may be configured to distribute a mechanical force exerted by clip lead. In some embodiments, a contact surface area of the substrate with respect to the die terminal may be greater than a contact surface area of the clip lead with respect to the substrate.

The substrate may be configured to bridge a difference between a coefficient of thermal expansion of the clip lead and a coefficient of thermal expansion of a die substrate of the semiconductor die. For example, the substrate may have a coefficient of thermal expansion that is lower than that of the clip lead. The die substrate may for example comprise a semiconductor material such as silicon, or sapphire, which typically have a lower coefficient of thermal expansion than the clip lead, which may be a metal such as copper.

Materials may expand or contract due to a change in temperature. In particular, different materials may expand at different rates and by different amounts. For example, the material forming the clip lead may typically expand more than the material forming the die substrate of the semiconductor die. Due to this differential in coefficient of thermal expansion, if the clip lead is fixedly attached to the die terminal, the clip lead may exert a thermomechanical force on the semiconductor die due to a greater expansion of the clip lead. This thermomechanical force may damage parts of the semiconductor die or may damage layers arranged on top of the semiconductor die. For example, typically, cracking may occur in a passivation layer or intermetallic dielectric layer on top of the semiconductor die under thermomechanical stress due to the force exerted by the clip lead.

In the semiconductor device package according to the present disclosure, a stress relief substrate may be provided that bridges a difference in thermal expansion coefficient between the clip lead and the semiconductor die. For example, the coefficient of thermal expansion of the substrate may be closer to that of the semiconductor die with respect to the clip lead. As such, the semiconductor die may experience less thermomechanical stress.

The substrate may comprise a dielectric material having arranged therein a plurality of conductive vias. The clip lead may be electrically connected to the die terminal through said plurality of conductive vias. In some embodiments, the substrate may comprise a printed circuit board, ‘PCB’, including said dielectric material and conductive vias. The conductive vias may for example comprise a conductive material, such as copper, gold, aluminum, tungsten, nickel or graphene. The dielectric material may have a coefficient of thermal expansion that is closer to that of the semiconductor die with respect to the clip lead, and may thus be highly suitable to form the stress relief substrate. The conductive vias may provide the electrical short between the clip lead and the die terminal for electrically connecting said clip lead and said die terminal.

Alternatively, the substrate may comprise a crystalline or polycrystalline silicon material, and the clip lead may be electrically connected to the die terminal through said crystalline or polycrystalline material. Crystalline and polycrystalline silicon may have a thermal expansion coefficient that is closer to that of the semiconductor die with respect to the clip lead and may be highly suitable to form the stress relief substrate.

The clip lead may comprise a first end that is fixedly and electrically connected to the substrate. A contact surface area of the substrate with respect to the die terminal may be greater than a contact surface area of the clip lead with respect to the substrate.

The semiconductor device package may further comprise a package material that encapsulates the semiconductor die and the substrate. The clip lead may comprise a second end that is arranged externally to the package material. The package material may comprise a molding compound.

The die terminal may be arranged in a metal layer of a layer stack on top of the semiconductor die, the layer stack comprising a stack of one or more metal layers, one or more intermetallic dielectric layers and one or more passivation layers.

The semiconductor die may be arranged on a die pad. In some embodiments, the die pad may be conductive and may be electrically connected to the electronic component.

The semiconductor device package may further comprise a further semiconductor die having a further electronic component integrated thereon and having a first further die terminal that is electrically connected to the further electronic component. The first further die terminal may be fixedly and electrically connected to another die terminal of the semiconductor die. Furthermore, the semiconductor device package may further comprise a further clip lead, a first end thereof being fixedly and electrically connected to a second further die terminal of the further semiconductor die that is electrically connected to the further electronic component, and a second end thereof being arranged externally to the package material.

In some embodiments, a thickness of the further semiconductor die may correspond to a thickness of the substrate. This enables forming the clip lead and the further clip lead in a similar manner, even though the further clip lead may not have a substrate associated therewith. For example, the further semiconductor die and the substrate may have a thickness in a range between 100-200 micron, such as about 150 micron, though the present disclosure is not limited thereto.

The electronic component and/or, if applicable, the further electronic component may comprise a bipolar junction transistor (BJT) or a field-effect transistor (FET), such as a high electron mobility transistor (HEMT) or a power metal oxide semiconductor FET, MOSFET. In some embodiments, the electronic component and the further electronic component may together form a cascode circuit or a half-bridge circuit. In other words, the semiconductor die and the further semiconductor die may be arranged such that the terminals of the FET and of the HEMT are electrically connected in a manner to form a cascode or half-bridge circuit. In this manner, a cascode or half-bridge circuit can be conveniently packaged together in a single semiconductor device package that can additionally mitigate thermomechanical stress exerted by the clip lead.

The clip lead may be fixedly and electrically connected to the substrate using a conductive adhesive material. Additionally, or alternatively, the substrate is fixedly and electrically connected to the die terminal using a conductive adhesive material. Additionally, or alternatively, if applicable, the semiconductor die may be fixedly and electrically connected to the die pad using a conductive adhesive material. Additionally, or alternatively, the further clip lead may be fixedly and electrically connected to the second further die terminal using a conductive adhesive material. Additionally, or alternatively, the further semiconductor die may be fixedly and electrically connected to the another die terminal of the semiconductor die using a conductive adhesive material. In each of these embodiments, the conductive adhesive material may comprise a conductive epoxy, a solder layer, such as tin, or a sinter layer, such as sintered silver or copper, though the present disclosure is not related to a particular conductive adhesive material.

The clip lead and, if applicable, the further clip lead may be gullwing-shaped. Additionally, or alternatively, the semiconductor die and/or, if applicable, the further semiconductor die may be based on one of Silicon, ‘Si’, Gallium Nitride, ‘GaN’, Silicon Carbide, ‘SiC’, or Gallium Arsenide, ‘GaAs’, technology.

According to another aspect of the present disclosure, a method for manufacturing a semiconductor device package is provided, comprising the steps of a) providing a semiconductor die having an electronic component integrated thereon and having a die terminal that is electrically connected to the electronic component, b) providing a stress relief substrate as described above, and fixedly and electrically connecting said substrate to the die terminal, and c) providing a clip lead, wherein the substrate provides an electrical short between the clip lead and the die terminal.

The clip lead may comprise a first end that is fixedly and electrically connected to the substrate. In some embodiments, a contact surface area of the substrate with respect to the die terminal may be greater than a contact surface area of the clip lead with respect to the substrate.

Additionally, or alternatively, the method may further comprise the step of d) providing a package material, and arranging said package material to encapsulate the semiconductor die and the substrate, a second end of the clip lead being arranged externally to the package material. For example, the package material may be a molding compound, and step d may comprise applying said molding compound and allowing said molding compound to solidify to thereby form a body of solidified molding compound that encapsulates at least the substrate and the semiconductor die.

The semiconductor die may be fixedly arranged on a die pad, and the die pad may be comprised in a leadframe. In some embodiments, the die pad may be conductive and may be electrically connected to the electronic component. The leadframe may further comprise a frame portion to which the die pad is fixedly connected. The method may further comprise a step of e) singulating the semiconductor device package from the leadframe, for example by performing at least one of punching, drilling, cutting or sawing. In some embodiments, the leadframe may comprise a plurality of said frame portions and die pads for manufacturing a plurality of said semiconductor device packages.

Step b) may further comprise providing a further semiconductor die having a further electronic component integrated thereon and having a first further die terminal that is electrically connected to the further electronic component. The first further die terminal may be fixedly and electrically connected to another die terminal of the semiconductor die. Furthermore, step c) may further comprise providing a further clip lead, and fixedly and electrically connecting a first end thereof to a second further die terminal of the further semiconductor die that is electrically connected to the further electronic component. A second end thereof may be arranged externally to the package material. In some embodiments, a thickness of the further semiconductor die may correspond to a thickness of the substrate. The electronic component and/or, if applicable, the further electronic component may comprise a BJT or a FET, such as a HEMT or a power MOSFET. In some embodiments, the electronic component and the further electronic component may together form a cascode circuit or a half-bridge circuit.

The clip lead and, if applicable, the further clip lead may be comprised in one or more clips, wherein the one or more clips comprise a supporting portion that is arranged to be supported by or fixedly connected to the frame portion. Furthermore, the method may further comprise, after step d), separating the clip lead and, if applicable, the further clip lead from the supporting portion, for example by performing at least one of punching, drilling, cutting or sawing.

Fixedly and electrically connecting the clip lead to the substrate may be performed using a conductive adhesive material. Additionally, or alternatively, fixedly and electrically connecting the substrate to the die terminal may be performed using a conductive adhesive material. Additionally, or alternatively, fixedly and electrically connecting the semiconductor die to the die pad may be performed using a conductive adhesive material. Additionally, or alternatively, fixedly and electrically connecting the further clip lead to the second further die terminal may be performed using a conductive adhesive material. Additionally, or alternatively, fixedly and electrically connecting the further semiconductor die to the another die terminal of the semiconductor die may be performed using a conductive adhesive material. In some embodiments, the conductive adhesive material may comprise one of a conductive epoxy, a solder layer, such as tin, or a sinter layer, such as sintered silver or copper.

The clip lead and, if applicable, the further clip lead may be formed to be gullwing-shaped, for example by bending the second end of the clip lead and, if applicable, the further clip lead.

The semiconductor die and/or, if applicable, the further semiconductor die may be based on one of Silicon, ‘Si’, Silicon Carbide, ‘SiC’, Gallium Nitride, ‘GaN’, or Gallium Arsenide, ‘GaAs’, technology.

### BRIEF DESCRIPTION OF DRAWINGS

Next, the present disclosure will be described in more detail with reference to the appended figures, wherein:

FIG. 1A is a cross-sectional view of a semiconductor device package according to an embodiment of the present disclosure;

FIG. 1B is a top view of a semiconductor device package according to an embodiment of the present disclosure;

FIG. 2 is a cross-sectional view of a portion of the semiconductor device package shown in FIGS. 1A and 1B;

FIG. 3 is a top view of a substrate according to an embodiment of the present disclosure; and

FIGS. 4A, 4B, 4C, 4D, 4E, 4F, 4G, and 4H illustrate a manufacturing process for manufacturing a semiconductor device package according to an embodiment of the present disclosure.

### DETAILED DESCRIPTION

The present disclosure is described in conjunction with the appended figures. It is emphasized that, in accordance with the standard practice in the industry, various features are not drawn to scale. In fact, the dimensions of the various features may be arbitrarily increased or reduced for clarity of discussion.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the detailed description using the singular or plural number may also include the plural or singular number respectively. The word “or” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the detailed description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

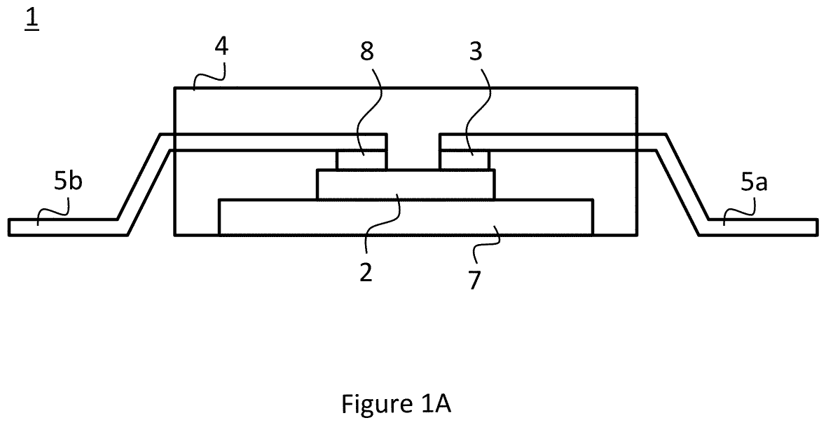

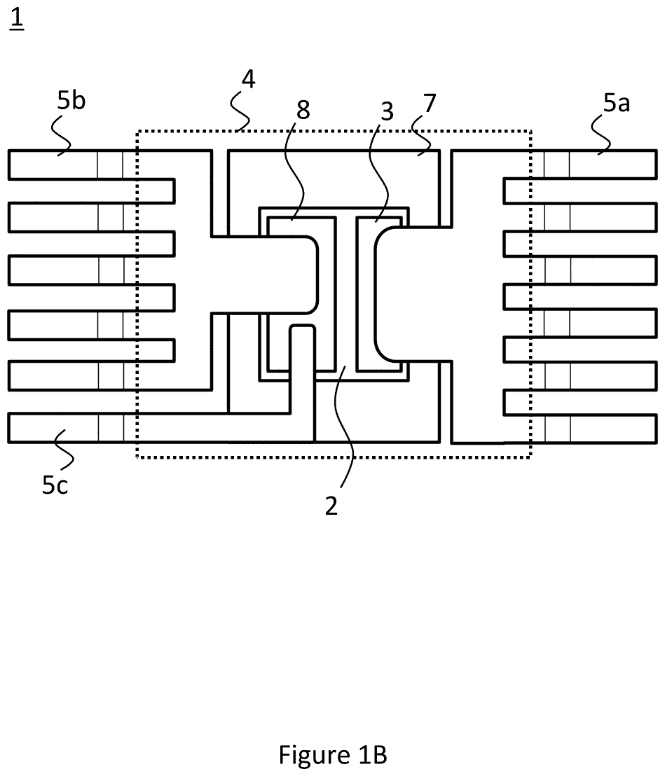

In FIG. 1A, a cross-sectional side view of a semiconductor device package 1 is shown according to an embodiment of the present disclosure.

Semiconductor device package 1 comprises a semiconductor die 2 that has an electronic component integrated thereon. Semiconductor die 2 is encapsulated by a package material 4 configured to protect semiconductor die 2 from external damage, such as mechanical stress. More in particular, semiconductor die 2 may be arranged on a die pad 7 and may support semiconductor die 2 and form a portion of a bottom surface of semiconductor device package 1.

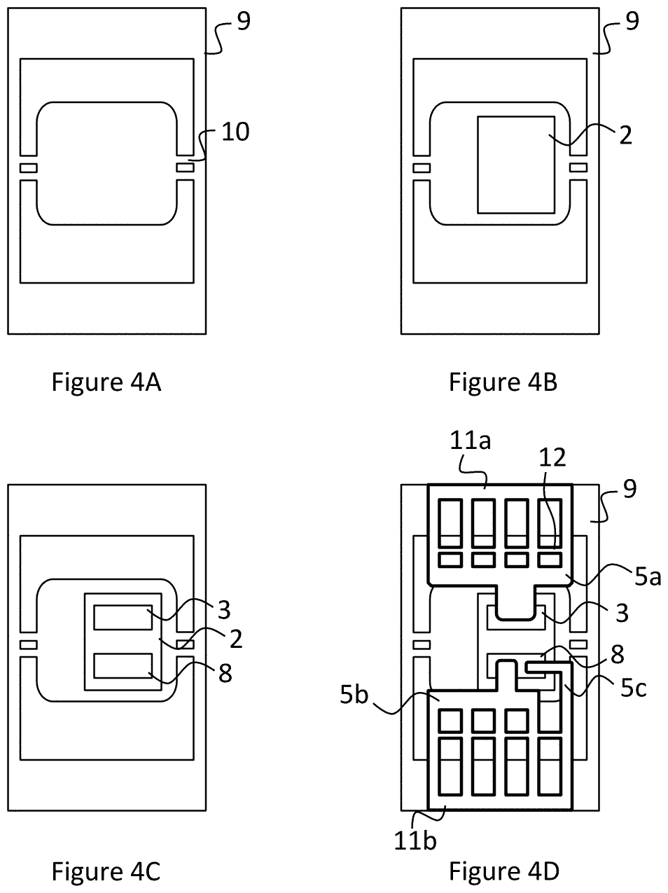

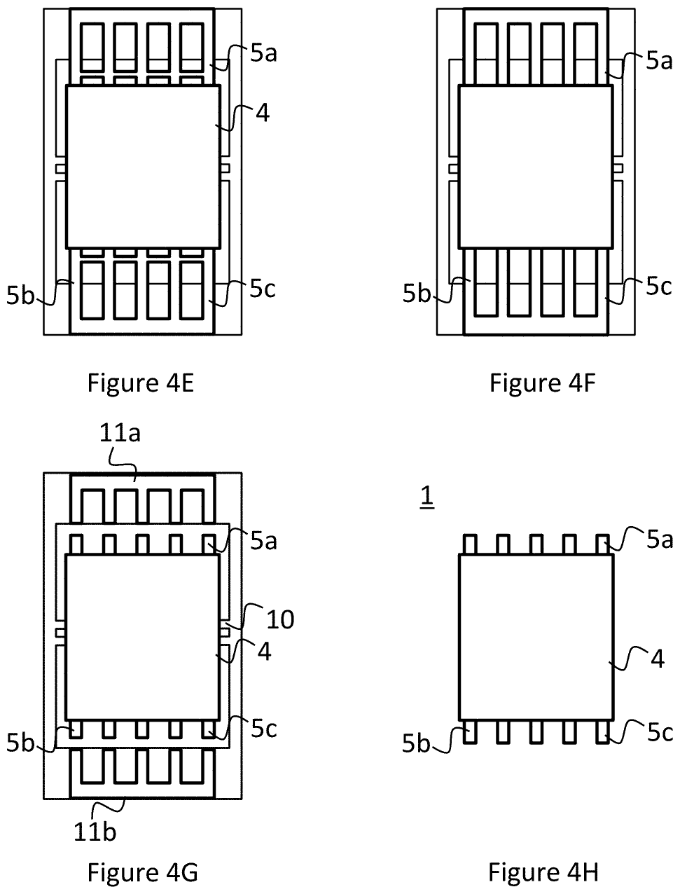

In some embodiments, die pad 7 may be omitted. For example, semiconductor die 2 could be arranged on a temporary carrier instead, which may be removed during the manufacturing process, which will be described in greater detail below with reference to FIGS. 4A-4H.

Typically, the electronic component may have one or more terminals that are accessible from an outside of semiconductor device package 1 through leads, such as a clip lead 5a and a further clip lead 5b. In particular, clip lead 5a and further clip lead 5b shown in FIG. 1A are gullwing-shaped leads, and a first end of each lead being arranged inside package material 4 and being fixedly and electrically connected to a component inside package material 4. On the other hand, a second end of clip lead 5a and further clip lead 5b is arranged externally to package material 4. For example, clip lead 5a and further clip lead 5b may be electrically connected to an external circuit via the second end(s). Furthermore, die pad 7 may be conductive, and may be arranged having an exposed bottom surface, as shown in FIG. 1A. Then, die pad 7 could be electrically connected to another terminal of the electronic component, and the bottom surface of die pad 7 may enable external access to said another terminal of the electronic component on semiconductor die 2.

In an example, semiconductor die 2 may be based on Gallium Nitride (GaN) technology, and the electronic component may be a high electron mobility transistor (HEMT).

Semiconductor device package 1 further comprises a substrate 3 fixedly and electrically connected to a die terminal (not shown), and clip lead 5a is fixedly and electrically connected to said substrate 3. Clip lead 5a is then electrically connected to the die terminal through at least a portion of substrate 3. The die terminal may be electrically connected to a terminal of the electronic component. For example, the die terminal is arranged in a metal layer on top of semiconductor die 2 and is electrically connected to a terminal of the electronic component using a metal interconnection, such as one or more vias.

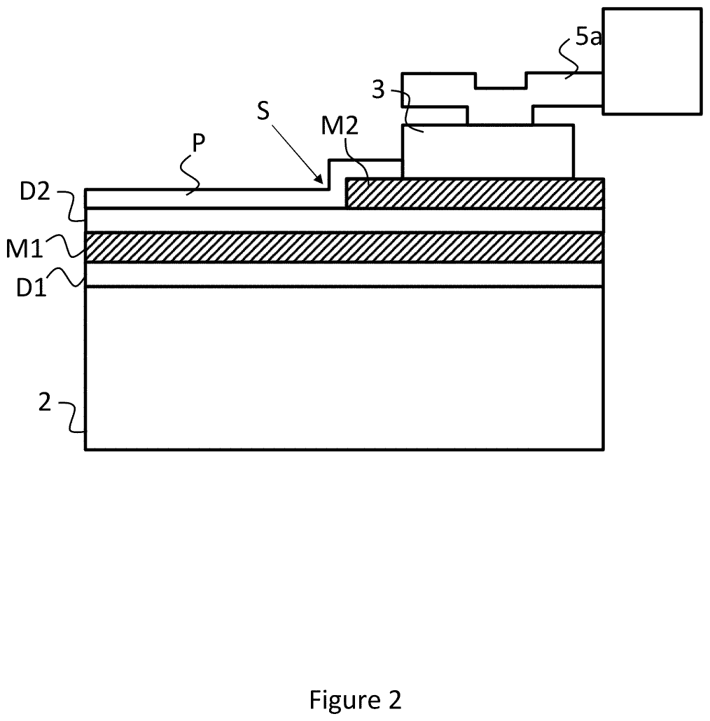

In some embodiments, semiconductor die 2 may comprise a layer stack (not shown in FIG. 1A) comprising one or more metal layers, one or more intermetallic dielectric layers, and one or more passive layers. The layer stack will be described in greater detail below with reference to FIG. 2.

Clip lead 5a is conductive and typically comprises a metal, such as copper. As a result, a coefficient of thermal expansion thereof may be relatively large with respect to that of semiconductor die 2, in particular a substrate thereof. Due to this difference in coefficient of thermal expansion, a thermomechanical force may be exerted by clip lead 5a on semiconductor die 2 due to a change in temperature, causing potential damages to semiconductor die 2 and possibly even failure of the electronic component integrated thereon. By using substrate 3, stress exerted by an expansion or contraction of clip lead 5a due to a change in temperature is distributed, and a stress exerted on semiconductor die 2 is mitigated. By distributing said force and reducing the stress exerted on semiconductor die 2, a more robust package can be obtained.

A contact surface area of clip lead 5a, by which clip lead 5a is fixedly connected, may be smaller than a contact surface area of substrate 3 by which substrate 3 is fixedly connected to the die terminal.

In some embodiments, semiconductor device package 1 further comprises a further semiconductor die 8. Further semiconductor die 8 may have a further electronic component integrated thereon. For example, the further electronic component may be a field-effect transistor (FET). Further semiconductor die 8 may be fixedly and electrically connected to a die terminal of semiconductor die 2. As such, a terminal of the further electronic component may be electrically connected to a terminal of the electronic component, internally to semiconductor device package 1. Further clip lead 5b may be fixedly and electrically connected to further semiconductor die 8 and may provide external access to another terminal of further electronic component.

The combined circuit formed by the electronic component and the further electronic component may be a cascoded transistor circuit, or a half-bridge circuit. However, the present disclosure also envisages other types of combined circuits to be packaged in semiconductor device package 1. Furthermore, the electronic component and the further electronic component are described as being transistors, the present disclosure is not limited thereto. As an example only, the electronic component or circuit integrated on semiconductor die 2 and/or further semiconductor die 8 may instead be a diode, silicon-controlled rectifier, or the like, or may be combinations of various types of electronic components.

Alternatively, or additionally to the above, although only one substrate 3 is shown, one or more other die terminals of semiconductor die 2 may have a respective substrate associated therewith for relieving thermomechanical stress. For example, in absence of further semiconductor die 8, further clip lead 5b may instead be fixedly and electrically connected to another die terminal of semiconductor die 2.

In FIG. 1B, an exemplary top view is shown corresponding to semiconductor device package 1 as shown in FIG. 1A.

As shown in FIG. 1B, clip lead 5a and further clip lead 5b may comprise a plurality of second ends arranged externally to package material 8. The first end of clip lead 5a is fixedly and electrically connected to a top surface of substrate 3, and the first end of further clip lead 5b is fixedly and electrically connected to a top surface of further semiconductor die 8, for example to a die terminal thereof.

In some embodiments, the electronic component integrated on semiconductor die 2 is a first transistor (e.g., a FET), and the further electronic component integrated on further semiconductor die 8 is a second transistor (e.g., a HEMT). For example, further clip lead 5b may correspond to a source terminal of the first transistor, and the drain terminal of the first transistor may be arranged at a bottom surface of further semiconductor die 8 and may be electrically connected to a source terminal of the second transistor. Clip lead 5a may correspond to a drain terminal of the second transistor and die pad 7 may correspond to a gate terminal of the second transistor. Semiconductor die package 1 may further comprise another further clip lead 5c fixedly and electrically connected to another die terminal of further semiconductor die 8, and may correspond to a gate terminal of the second transistor.

In FIG. 2, a cross-sectional view of semiconductor die 2 is shown having a layer stack arranged on top, according to an embodiment of the present disclosure. In particular, the layer stack comprises a plurality of metal layers M1, M2, a plurality of intermetallic dielectric layers D1, D2, and a passivation layer P. Although not shown, portions of metal layers M1, M2 may be interconnected using vias. Here, it is noted that the term ‘metal layer’ may refer to a plurality of separate portions, for example arranged on a same passivation layer or intermetallic dielectric layer.

In the example shown in FIG. 2, the die terminal corresponds to a portion of metal layer M2. Substrate 3 is fixedly and electrically connected to said portion of metal layer M2, and clip lead 5a is in turn fixedly and electrically connected to substrate 3. As shown in FIG. 2, the contact surface area of substrate 3 may be greater than the contact surface area of clip lead 5a.

The Applicant has found that, in absence of substrate 3, the package may fail due to short circuits between metal layers of the layer stack. For example, in a high temperature reverse bias (HTRB) test, the Applicant found that stress-related concerns are observed under clip lead 5a in absence of substrate 3. The stress-related concerns correspond to thermomechanical stress leading to micro-cracks in the layers of the layer stack. Typically, such cracks can start in passivation layer P at a position S indicated in FIG. 2, and may propagate into intermetallic dielectric layer D2. For example, in absence of substrate 3, cracking may occur at position S due to a force exerted by clip lead 5a on semiconductor die 2 and/or the layers on top of semiconductor die 2 including passivation layer P. Due to the cracking, at a reverse bias, a leakage path can be observed between metal layers M2 and M1. The cracking may at least partially occur due to a difference in thermal expansion of clip lead 5a and the die substrate of semiconductor die 2. In particular, the layer stack on top of semiconductor die 2 may be relatively small with respect to the die substrate of semiconductor die 2. As a result, thermal expansion of semiconductor die 2 is typically dominated by the die substrate of semiconductor die 2.

As described above, by including substrate 3, the stress on semiconductor die 2, such as on the layers of the layer stack, can be reduced significantly. For example, substrate 3 may bridge a difference in coefficient of thermal expansion between clip lead 5a and semiconductor die 2 (or, more particularly, its substrate), and/or may distribute a force exerted by clip lead 5a.

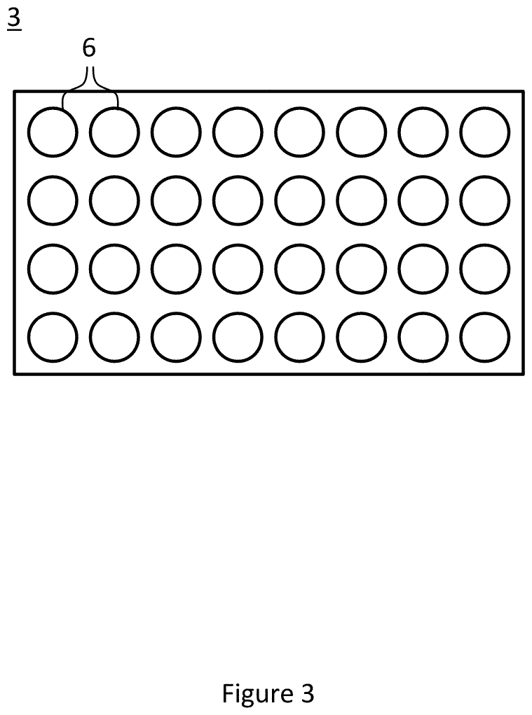

In FIG. 3, a top view of substrate 3 according to an embodiment of the present disclosure is shown. In some embodiments, substrate 3 comprises a dielectric layer, such as a PCB, in which a plurality of conductive vias 6 are arranged. Conductive vias 6 may for example be copper or copper-plated vias. A coefficient of thermal expansion of the dielectric layer (e.g., the PCB) may be closer to a coefficient of thermal expansion of semiconductor die 2 (e.g., passivation layers P1-P3 and/or intermetallic dielectric layers D1-D2) compared to clip lead 5a. In some embodiments, the conductive vias 6 are mutually electrically connected via a metal layer (not shown) arranged on one or both of a top side and a bottom side of substrate 3, and conductive vias 6 may extend between said top side and said bottom side.

Conductive vias 6 may occupy a particular amount of a volume of substrate 3. In an example, conductive vias 6 may together form 10-90% of the volume of substrate 3. For example, 50% of the volume of substrate 3 is comprised of conductive vias 6. However, the present disclosure is not limited to any such amount, and the preferred or optimal amount may depend on the application.

Alternatively, to the configuration shown in FIG. 3, substrate 3 may comprise a crystalline or polycrystalline silicon material. Polysilicon material may have a coefficient of thermal expansion that is closer to a coefficient of thermal expansion of semiconductor die 2 and may additionally be conductive to provide an electrical short between clip lead 5a and the corresponding die terminal.

Next, a process for manufacturing semiconductor device package 1 according to some embodiments of the present disclosure is described with reference to FIGS. 4A-4H.

In FIG. 4A, a leadframe is provided comprising a frame portion 9 and die pad 7. In particular, die pad 7 may be fixedly attached to frame 9 via tie bars 10. The leadframe may comprise a plurality of said frame portions 9 and a plurality of said die pads 7 for manufacturing a plurality of semiconductor device packages substantially simultaneously. For example, a plurality of frame portions 9 and corresponding die pads 7 may be arranged in a row or in an array during manufacturing. In the ensuing description below, each step may be performed for multiple or each of said frame portions 9 and die pads 7.

Next, in FIG. 4B, semiconductor die 2 is fixedly connected to die pad 7, for example using a conductive adhesive material. As an example only, the conductive adhesive material may comprise a solder layer, such as tin, or a sinter layer, such as sintered silver or sintered copper. As described above, if die pad 7 is conductive, then die pad 7 may additionally be electrically connected to a terminal of the electronic component integrated on semiconductor die 2 via said conductive adhesive material.

In FIG. 4C, substrate 3 is fixedly and electrically connected to a die terminal of semiconductor die 2. Optionally, a substrate is provided for a plurality of terminals at a top surface of semiconductor die 2. Furthermore, for manufacturing a package comprising a cascode or half-bridge circuit, further semiconductor die 8 may be fixedly and electrically connected to another die terminal of semiconductor die 2, as detailed above. Substrate 3 and, if applicable, further semiconductor die 8 may be fixedly and electrically connected to die terminals of semiconductor die 2 using a conductive adhesive material, similarly to how semiconductor die 2 could be attached to die pad 7.

In FIG. 4D, clips are provided, the clips comprising the leads. For example, a first clip is provided comprising clip lead 5a, and a second clip is provided comprising further clip lead 5b and another further clip lead 5c.

The first clip may have a first portion, corresponding to clip lead 5a, that is fixedly and electrically connected to substrate 3, and may have a supporting portion 11a that is supported by or fixedly connected to frame portion 9. The second ends of clip lead 5a may further be interconnected by dam-bars 12. The second clip may be provided in a similar manner. In particular, further clip lead 5b and another further clip lead 5c of the second clip may be fixedly and electrically connected to further semiconductor die 8, and its supporting portion 11 b may be supported by or fixedly connected to frame portion 9. In an alternative embodiment, a separate clip (not shown) is provided for further clip lead 5b and further clip lead 5c, each separate clip comprising a separate supporting portion.

Here, it is noted that clip lead 5a and further clip leads 5b, 5c may be fixedly connected to substrate 3 and further semiconductor die 8, respectively, using a conductive adhesive material, such as a solder layer or a sinter layer. Furthermore, when manufacturing a plurality of packages simultaneously, the first clip and the second clip may be individually attached for each package in the row or array, or they may be provided in a clip frame matrix comprising a plurality of first clips and second clips. At a later stage, the first and second clips corresponding to different packages may be separated from one another.

In FIG. 4E, package material 4 is arranged to encapsulate semiconductor die 2, substrate 3, and , if applicable, further semiconductor die 8. As shown in FIG. 4E, a portion of the first and second clip, in particular second ends of clip lead 5a and further clip leads 5b, 5c, are arranged externally to package material 4. As an example only, arranging package material 4 may comprise applying a molding compound and allowing said molding compound to solidify to thereby form a body of solidified molding compound.

In FIG. 4F, dam-bars 12 between the second ends of clip lead 5a and further clip leads 5b, 5c are removed. For example, removing dam-bars 12 may comprise one or more of punching, drilling, cutting or sawing.

In FIG. 4G, the second end(s) of clip lead 5a and further clip leads 5b, 5c are separated from supporting portions 11a, 11b of the first and second clip, respectively. For example, the separating may comprise one or more of punching, drilling, cutting or sawing.

Finally, in FIG. 4H, semiconductor device package 1 is obtained by singulating the package from frame portion 9. For example, the step of singulating may comprise punching, drilling, cutting or sawing tie bars 10 to separate semiconductor device package 1 from the leadframe. At this stage, the second end(s) of clip lead 5a and further clip leads 5b, 5c may be formed in a particular shape, for example by means of bending. As an example only, the second end(s) of clip lead 5a and further clip leads 5b, 5c may be formed so as to be gullwing-shaped. However, it is noted that shaping the second ends may also be performed prior to singulation.

The ensuing description above provides preferred exemplary embodiment(s) only, and is not intended to limit the scope, applicability or configuration of the disclosure. Rather, the ensuing description of the preferred exemplary embodiment(s) will provide those skilled in the art with an enabling description for implementing a preferred exemplary embodiment of the disclosure, it being understood that various changes may be made in the function and arrangement of elements, including various modifications and/or combinations of features from different embodiments, without departing from the scope of the present disclosure as defined by the appended claims.

What is claimed is:

1. A leadframe-based semiconductor device package, comprising:
a semiconductor die having an electronic component integrated thereon and having a die terminal that is electrically connected to the electronic component;
a stress relief substrate fixedly and electrically connected to the die terminal;
a clip lead; and
wherein the substrate is configured to provide an electrical short between the clip lead and the die terminal.

2. The semiconductor device package according to claim 1, wherein the substrate is configured to distribute a mechanical force exerted by the clip lead.

3. The semiconductor device package according to claim 1, wherein the substrate is configured to bridge a difference between a coefficient of thermal expansion of the clip lead and a coefficient of thermal expansion of a die substrate of the semiconductor die, and wherein the substrate has a coefficient of thermal expansion that is lower than that of the clip lead.

4. The semiconductor device package according to claim 1, wherein the substrate comprises a dielectric material having arranged therein a plurality of conductive vias, wherein the clip lead is electrically connected to the die terminal through the plurality of conductive vias, wherein the substrate comprises a printed circuit board (PCB), including the dielectric material and conductive vias, wherein the conductive vias comprises a conductive material, selected from the group consisting of copper, gold, aluminum, tungsten, nickel and graphene; or
wherein the substrate comprises a crystalline or polycrystalline material, wherein the clip lead is electrically connected to the die terminal through the crystalline or polycrystalline material.

5. The semiconductor device package according to claim 1, wherein the clip lead comprises a first end that is fixedly and electrically connected to the substrate, and
wherein the substrate has a contact surface area with respect to the die terminal that is greater than a contact surface area of the clip lead with respect to the substrate, and/or
wherein the semiconductor device package further comprises a package material that encapsulates the semiconductor die and the substrate, wherein the clip lead comprises a second end that is arranged externally to the package material, wherein the package material comprises a molding compound.

6. The semiconductor device package according to claim 1, wherein the die terminal is arranged in a metal layer of a layer stack on top of the semiconductor die, the layer stack comprising a stack of one or more metal layers, one or more intermetallic dielectric layers and one or more passivation layers; and/or
wherein the semiconductor die is arranged on a die pad, wherein the die pad is conductive and electrically connected to the electronic component.

7. The semiconductor device package according to claim 1, wherein the clip lead and the further clip lead are gullwing-shaped; and/or
wherein the semiconductor die and/or the further semiconductor die is based on one technology selected from the group consisting of Silicon, Silicon Carbide, Gallium Nitride, and Gallium Arsenide technology.

8. The semiconductor device package according to claim 2, wherein the substrate is configured to bridge a difference between a coefficient of thermal expansion of the clip lead and a coefficient of thermal expansion of a die substrate of the semiconductor die, and wherein the substrate has a coefficient of thermal expansion that is lower than that of the clip lead.

9. The semiconductor device package according to claim 2, wherein the substrate comprises a dielectric material having arranged therein a plurality of conductive vias, and wherein the clip lead is electrically connected to the die terminal through the plurality of conductive vias, and
wherein the substrate comprises a printed circuit board (PCB), including the dielectric material and conductive vias, wherein the conductive vias comprises a conductive material, selected from the group consisting of copper, gold, aluminum, tungsten, nickel and graphene; or
wherein the substrate comprises a crystalline or polycrystalline material, wherein the clip lead is electrically connected to the die terminal through the crystalline or polycrystalline material.

10. The semiconductor device package according to claim 2, wherein the clip lead comprises a first end that is fixedly and electrically connected to the substrate, and wherein the substrate has a contact surface area with respect to the die terminal that is greater than a contact surface area of the clip lead with respect to the substrate, and/or
wherein the semiconductor device package further comprises a package material that encapsulates the semiconductor die and the substrate, wherein the clip lead comprises a second end that is arranged externally to the package material, wherein the package material comprises a molding compound.

11. The semiconductor device package according to claim 2, wherein the die terminal is arranged in a metal layer of a layer stack on top of the semiconductor die, the layer stack comprising a stack of one or more metal layers, one or more intermetallic dielectric layers and one or more passivation layers; and/or
wherein the semiconductor die is arranged on a die pad, wherein the die pad is conductive and electrically connected to the electronic component.

12. The semiconductor device package according to claim 6, further comprising:
a further semiconductor die having a further electronic component integrated thereon and having a first further die terminal that is electrically connected to the further electronic component, wherein the first further die terminal is fixedly and electrically connected to another die terminal of the semiconductor die; and
a further clip lead, a first end thereof being fixedly and electrically connected to a second further die terminal of the further semiconductor die that is electrically connected to the further electronic component, and a second end thereof being arranged externally to the package material,
wherein the further semiconductor die has a thickness that corresponds to a thickness of the substrate, and/or wherein the electronic component and/or, the further electronic component comprises a bipolar junction transistor (BJT), or a field-effect transistor (FET), or a power metal oxide semiconductor FET (MOSFET), wherein the electronic component and the further electronic component together form a cascode circuit or a half-bridge circuit.

13. The semiconductor device package according to claim 12,
wherein the clip lead is fixedly and electrically connected to the substrate using a conductive adhesive material; and/or
wherein the substrate is fixedly and electrically connected to the die terminal using a conductive adhesive material; and/or
wherein the semiconductor die is fixedly and electrically connected to the die pad using a conductive adhesive material; and/or
wherein the further clip lead is fixedly and electrically connected to the second further die terminal using a conductive adhesive material; and/or
wherein the further semiconductor die is fixedly and electrically connected to the another die terminal of the semiconductor die using a conductive adhesive material; and
wherein the conductive adhesive material comprises a conductive epoxy, a solder layer, or a sinter layer.

14. A method for manufacturing a semiconductor device package, the method comprising the steps of:
a) providing a semiconductor die having an electronic component integrated thereon and having a die terminal that is electrically connected to the electronic component;
b) providing a stress relief substrate as defined in claim 1, and fixedly and electrically connecting the substrate to the die terminal; and
c) providing a clip lead, wherein the substrate provides an electrical short between the clip lead and the die terminal.

15. The method according to claim 14, wherein the clip lead comprises a first end that is fixedly and electrically connected to the substrate, wherein the substrate has a contact surface area with respect to the die terminal is greater than a contact surface area of the clip lead with respect to the substrate; and/or
wherein the method further comprises the step of:
d) providing a package material, a molding compound, and arranging the package material to encapsulate the semiconductor die and the substrate, wherein the clip lead has a second end that is arranged externally to the package material.

16. The method according to claim 14, wherein the semiconductor die is fixedly arranged on a die pad, the die pad being comprised in a leadframe, and wherein the die pad is conductive and is electrically connected to the electronic component,
wherein the leadframe further comprises a frame portion to which the die pad is fixedly connected, and wherein the method further comprises a step e) of singulating the semiconductor device package from the leadframe, by performing at least one action selected from the group consisting of punching, drilling, cutting and sawing; and
wherein the leadframe comprises a plurality of the frame portions and die pads for manufacturing a plurality of the semiconductor device packages.

17. The method according to claim 14, wherein the clip lead and the further clip lead are comprised in one or more clips, wherein the one or more clips comprise a supporting portion that is arranged to be supported by or fixedly connected to the frame portion,
wherein the method further comprises, after step d), separating the clip lead and, the further clip lead from the supporting portion, by performing at least one of punching, drilling, cutting or sawing.

18. The method according to claim 16, wherein step b) further comprises providing a further semiconductor die having a further electronic component integrated thereon and having a first further die terminal that is electrically connected to the further electronic component, wherein the first further die terminal is fixedly and electrically connected to another die terminal of the semiconductor die, and
wherein step c) further comprises providing a further clip lead, and fixedly and electrically connecting a first end thereof to a second further die terminal of the further semiconductor die that is electrically connected to the further electronic component, and a second end thereof is arranged externally to the package material;
wherein the further semiconductor die has a thickness that corresponds to a thickness of the substrate, and/or wherein the electronic component and/or, the further electronic component comprises a bipolar junction transistor, (BJT), or a field-effect transistor (FET), or a power metal oxide semiconductor FET (MOSFET), wherein the electronic component and the further electronic component together form a cascode circuit or a half-bridge circuit.

19. The method according to claim 18, further comprising a conductive adhesive material, comprising one material selected from the group consisting of a conductive epoxy, a solder layer, and a sinter layer, is used for at least one of the following:
fixedly and electrically connecting the clip lead to the substrate;
fixedly and electrically connecting the substrate to the die terminal;
fixedly and electrically connecting the semiconductor die to the die pad;
fixedly and electrically connecting the further clip lead to the second further die terminal;
fixedly and electrically connecting the further semiconductor die to the another die terminal of the semiconductor die;
and/or
wherein the clip lead and, the further clip lead are formed to be gullwing-shaped, by bending the second end of the clip lead and, the further clip lead;
and/or
wherein the semiconductor die and/or, the further semiconductor die is based on one technology selected from the group consisting of Silicon, Silicon Carbide, Gallium Nitride, and Gallium Arsenide technology.

20. The method according to claim 18, further comprising a conductive adhesive material, comprising one material selected from the group consisting of a conductive epoxy, a solder layer, and a sinter layer, is used for at least one of the following:
fixedly and electrically connecting the clip lead to the substrate;
fixedly and electrically connecting the substrate to the die terminal;
fixedly and electrically connecting the semiconductor die to the die pad;
fixedly and electrically connecting the further clip lead to the second further die terminal;
fixedly and electrically connecting the further semiconductor die to the another die terminal of the semiconductor die.
